(19) United States
(12) Patent Application Publication
(10) Pub. No.: US 2014/0345669 A1
(43) Pub. Date: Nov. 27, 2014

(54) METHOD OF PRODUCING TWO OR MORE THIN-FILM-BASED INTERCONNECTED PHOTOVOLTAIC CELLS

(71) Applicant: Dow Global Technologies LLC, Midland, MI (US)

(72) Inventors: Rebekah K. Feist, Midland, MI (US); Michael E. Mills, Midland, MI (US)

(73) Assignee: Dow Global Technologies LLC, Midland, MI (US)

(21) Appl. No.: 14/364,395

(22) PCT Filed: Dec. 11, 2012
(86) PCT No.: PCT/US2012/068864

§ 371 Date: Jun. 11, 2014

Related U.S. Application Data
(60) Provisional application No. 61/578,300, filed on Dec. 21, 2011.

(51) Int. Cl. H01L 27/142; H01L 31/18

(52) U.S. Cl. CPC H01L 27/1426; H01L 31/1884
USPC 136/244; 438/73

(57) ABSTRACT

The present invention is directed to a method of producing two or more thin-film-based interconnected photovoltaic cells (100) comprising the steps of: a) providing a photovoltaic article comprising: a flexible conductive substrate, at least one photoelectrically active layer, and a top transparent conducting layer; b) forming one or more first channels (140) through the flexible conductive substrate to expose a portion of the photoelectrical]?—active layer; e) applying an insulating segment to the conductive substrate and spanning the one or more first-channel; d) forming one or more second channels off set from the one or more first channels—‘through—the photoelectrically active layer to expose a conductive surface of the flexible conductive substrate; I) forming one or more third channels (170) off set from both the first channels and the second channels, through the top transparent conducting layer and to the photoelectrically active layer: and g) applying an electrically conductive material (180) above the top transparent conducting layer and in the second channels, thus producing two or more Interconnected photovoltaic cells.

### FIELD OF THE INVENTION

The present invention relates to an improved method of producing two or more thin-film-based interconnected photovoltaic cells, more particularly to an improved method of producing two or more thin-film-based interconnected photovoltaic cells from a photovoltaic article that includes a flexible conductive substrate, at least one photoelectrically active layer, and a top transparent conducting layer.

### BACKGROUND

Efforts to improve the manufacture of photovoltaic devices, particularly thin-film-based interconnected photovoltaic cells have been the subject of much research and development of the recent past. Of particular interest is the ability to manufacture thin-film-based interconnected photovoltaic cells in a variety of shapes and sizes, while maintaining efficient production and a relatively low capital investment, thus making the finished product more affordable. It has been a goal of the industry to develop these process and techniques that can help make the finished product more affordable, while still producing quality product.

In one application, these thin-film based interconnected photovoltaic cells are used as the electricity generating component of larger photovoltaic devices. The available shapes and sizes of relatively low cost thin-film-based interconnected photovoltaic cells may limit the design of the larger photovoltaic devices and systems of devices, and thus the possible market for them. To make this full package desirable to the consumer, and to gain wide acceptance in the marketplace, the system should be inexpensive to build and install. The present invention ultimately may help facilitate louver generated cost of energy, making PV technology more competitive relative to other means of generating electricity.

It is believed that the existing art for the manufacture of thin-film-based interconnected photovoltaic cells have relied upon methods and techniques that utilize interconnect steps prior to the completing of the photovoltaic article, for example wherein at least one scribe or cut is made during the article fabrication process.

Among the literature that can pertain to this technology include the following literature and U.S. patent documents: F. Kessler at al, “Flexible and monolithically integrated CIGS-modules”, MRS 668: H3.6.1-H3.6.6 (2001); U.S. Pat. Nos. 4,754,544; 4,697,041 5,131,954; 5,639,314; 6,372,538; 7,122,398; and 2010/1236490, all incorporated herein by reference for all purposes.

### SUMMARY OF THE INVENTION

The present invention is directed to a PV device that addresses at least one or more of the issues described in the above paragraphs.

Accordingly, pursuant to one aspect of present invention there is contemplated a method of producing two or more thin-film-based interconnected photovoltaic cells comprising the steps of: a) providing a photovoltaic article comprising: a flexible conductive substrate, at least one photoelectrically active layer, and a top transparent conducting layer; b) forming one or more first channels through the flexible conductive substrate to expose a portion of the photoelectrically active layer; c) applying an insulating segment to the conductive substrate lower layer and spanning the one or more first channel; d) forming on or more second channels off set from the one or more first channels through the photoelectrically active layer (and preferably also through the transparent conducting layer) to expose a conductive surface of the flexible conductive substrate; f) forming one or more third channels off set from both the first channels and the second channels, through the top transparent conducting layer and to the photoelectrically active layer; and g) applying an electrically conductive material above the top transparent conducting layer and in the second channels, thus producing two or more interconnected photovoltaic cells.

The invention may be further characterized by one or any combination of the features described herein, such as the step of at least partially filling the at least one third off-set channels with an electrically insulating material; the electrically insulating material comprises silicon oxide, silicon nitride, titanium oxide, aluminum oxide, non-conductive epoxy, silicone, polyester, polyfluorene, polyolefin, polyimide, polyamide, polyethylene or combinations of the like; the insulating segment comprises polyester, polyolefin, polyimide, polyamide, polyethylene; forming step is carried out by scribing, cutting, ablating, or combinations of the like; the photovoltaic article cell is in roll form; the electrically insulating material functions as a bottom carrier film; the third off-set channels of the forming step (f) go at least partially through the photoelectrically active layer; and the width of the channels of the forming step are between 10-500 microns.

It should be appreciated that the above referenced aspects and examples are non-limiting, as others exist within the present invention, as shown and described herein.

### DESCRIPTION OF THE DRAWINGS

FIG. 1A shows the layers of a photovoltaic article.

FIG. 1B shows the layers of a photovoltaic article with a first channel.

FIG. 1C shows the layer of a photovoltaic article with a first channel and an insulating layer.

FIG. 1D shows the layers of a photovoltaic article with a first channel, second channel, a third channel and an insulating layer.

FIG. 1E shows the layers of a photovoltaic article with a first channel, a second channel having electrically conductive material therein, a third channel and an insulating layer.

FIG. 2 shows an alternative embodiment of the layer photovoltaic article.

### DETAILED DESCRIPTION OF THE PREFERRED EMBODIMENT

The present invention relates to an improved method of producing two or more thin-film-based interconnected photovoltaic cells from a photovoltaic article that includes a flexible conductive substrate, at least one photoelectrically active layer, and a top transparent conducting layer. It is contemplated that the present invention provides a unique manufacturing solution that allows for the creation and interconnection of photovoltaic cells (e.g. two or more) from a photovoltaic article that is essentially already fabricated. The present invention may allow for thin-film-based interconnected photovoltaic cells with unique shapes and sizes to be manufactured with relatively low capital investment and without dedicated equipment or processes within the photovoltaic article manufacturing lines. Taught within this disclosure is the inventive method, as well as an explanation of the structure some of the typical photovoltaic articles that may be used as the inputs to the inventive process. The disclosed photovoltaic article discussed herein should not be considered limiting on the inventive method and other possible base photovoltaic articles are contemplated.

### Method

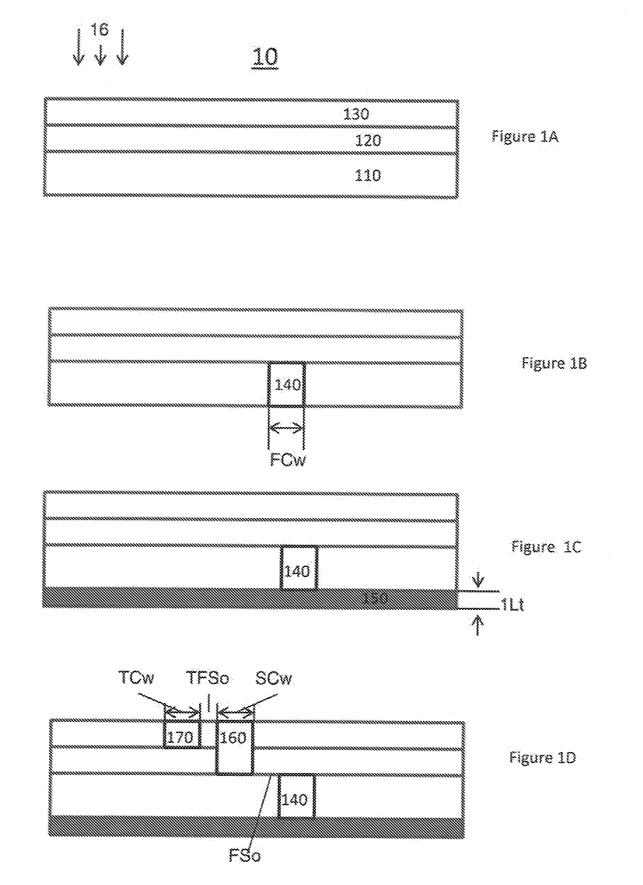

It is contemplated that the inventive method functions to take a base photovoltaic article 10 and transform it into interconnected photovoltaic cells 100, independent of the manufacturing of the base article. FIG. 1A is a representative example of the article 10 and method of this invention. The inventive method includes at least the steps of: a) providing a photovoltaic article 10 comprising a flexible conductive substrate 110 least one photoelectrically active layer 120, and a top transparent conducting layer 130; b) forming one or more first channels 140 through the flexible conductive substrate 110 to expose a portion of the photoelectrically active layer 120; c) applying an insulating segment 150 to the conductive substrate 110 and spanning the one or more first channel 140; d) fanning one or more second channels 160 off set from the one or more first channels 140 through the photoelectrically active layer to expose a conductive surface of the flexible conductive substrate 110; f) forming one or more third channels 170 off set from both the first channels 140 and the second channels 150 through the top transparent conducting layer 130 and to the photoelectrically active layer 120; and g) applying an electrically conductive material 180 above the top transparent conducting layer and in the second channels, thus producing two or more interconnected photovoltaic cells. Optional steps may include one or more of the following: at least partially filling the at least one third off-set channels with an electrically insulating material; providing a carrier film top layer; removing the carrier film top layer, thus exposing the top contact layer; packaging with protective layers; forming interconnects to external electric devices; packaging in module format (e.g. shingle); or using as part of a photovoltaic cell as described in US Publication 2011/0100436.

### Photovoltaic Article 10

It is contemplated that a photovoltaic article 10 is provided in the beginning of the inventive method/process. The article 10 is the basis for the creation of multiple interconnected photovoltaic cells 100 through this inventive method/process. The article should be comprised of at least three layers (list from bottom to top of the article): a flexible conductive substrate 110, at least one photoelectrically active layer 120, and a top transparent conducting layer 130. It is contemplated that the substrate or layers disclosed within this application may comprise a single layer, but any of these independently can be formed from multiple sublayers as desired. Additional layers conventionally used in photovoltaic articles as presently known or hereafter developed may also be provided. It is contemplated that presently known photovoltaic articles for use in the present invention may include: group IB-IIIB chalcogenide type cells (e.g. copper indium gallium selenides, copper indium selenides, copper indium gallium sulfides, copper indium sulfides, copper indium gallium selenides sulfides, etc.), amorphous silicon, III-V (i.e. GaAs), II-IV (i.e. CdTe), copper zinc tin sulfide, organic photovoltaics, nanoparticle photovoltaics, dye sensitized solar cells, and combinations of the like.

Additional optional layers (not shown) may be used on the article 10 in accordance with conventional practices now known or hereafter developed to help enhance adhesion between the various layers. Additionally, one or more barrier layers (not shown) also may be provided over the backside of flexible conductive substrate 110 to help isolate device 10 from the environment and/or to electrically isolate device 10.

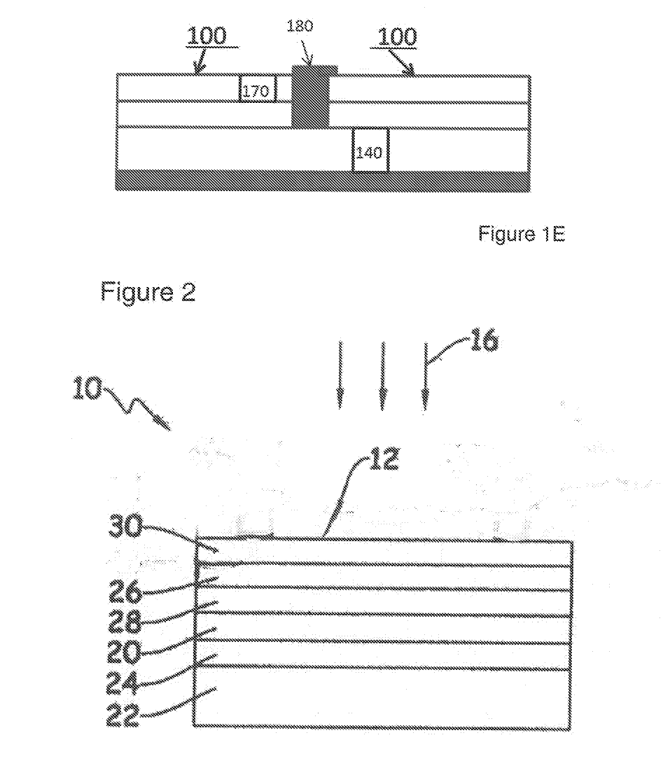

In one preferred embodiment, the photovoltaic article 10 provided as the base used in the inventive method/process is what is a group IB-IIIB chalcogenide device. FIG. 2 shows one embodiment of a photovoltaic article 10 that may be used in the processes of the present invention. In the layers describe below, it is contemplated that layers 22 and 24 together comprise the flexible conductive substrate, layer 20 is part of the least one photoelectrically active layer, and layer 30 is part of the top transparent conductive layer. This article 10 comprises a substrate incorporating a support 22, a backside electrical contact 24, and a chalcogenide absorber 20. The article 10 further includes an buffer region 28 comprising an n-type chalcogenide composition such as a cadmium sulfide based material. The buffer region preferably has a thickness of 15 to 200 nm. The article may also include an optional front side electrical contact window region 26. This window region protects the buffer during subsequent formation of the transparent conducting region 30. The window preferably is formed from a transparent oxide of zinc, indium, cadmium, or tin and is typically considered at least somewhat resistive. The Thickness of this layer is preferably 10 to 200 nm. The article further comprises a transparent conductive region 30. Each of these components is shown in FIG. 2 as including a single layer, but any of these independently can be formed from multiple sublayers as desired. Additional layers (not shown) conventionally used in photovoltaic cells as presently known or hereafter developed may also be provided. As used occasionally herein, the top 12 of the cell is deemed to be that side which receives the incident light 16. The method of forming the cadmium sulfide based layer on the absorber can also be used in tandem cell structures where two cells are built on top of each other, each with an absorber that absorbs radiation at different wavelengths.

### Flexible Conductive Substrate

It is contemplated that the photovoltaic article 10 has at least a flexible conductive substrate 110 that the article is built upon. It functions to provide a base upon which the other layers of the article are disposed upon. It also functions to provide electrical contact. It is contemplated that the substrate may be a single layer (e.g. stainless steel) or ma be a multilayer composite of many materials, both electrically conductive and non-conductive layers. Examples of conductive materials include metals (e.g. Cu, Mo, Ag, Au, Al, Cr, Ni, Ti, Ta, Nb, and W), conductive polymers, combinations of these, and the like. In one preferred embodiment, the substrate is comprised of stainless steel that has a thickness that is between about 10 μm and 200 μm. It is also preferred that the substrate is flexible, with “flexible” being defined as the “flexible” item, element, or layer (in a usable thickness pursuant to the present invention) that can bend about a 1 meter diameter cylinder without a decrease in performance or critical damage.

In the device shown in FIG. 2, the flexible conductive substrate comprises layers 22 and 24. The support 22 may be a flexible substrate. Support 22 may be formed from a wide range of materials. These include metals, metal alloys, intermetallic compositions, plastics, paper, woven or non-woven fabrics, combinations of these, and the like. Stainless steel is preferred. Flexible substrates are preferred to enable maximum utilization of the flexibility of the thin film absorber and other layers.

The backside electrical contact 24 provides a convenient way to electrically couple article 10 to external circuitry. Contact 24 may be formed from a wide range of electrically conductive materials, including one or more of Cu, Mo, Ag, Al, Cr, Ni, Ti, Ta, Nb, W, combinations of these, and the like. Conductive compositions incorporating Mo are preferred. The backside electrical contact 24 may also help to isolate the absorber 20 from the support 22 to minimize migration of support constituents into the absorber 20. For instance, backside electrical contact 24 can help to block the migration of Fe and Ni constituents of a stainless steel support 22 into the absorber 20. The backside electrical contact 24 also can protect the support 22 such as by protecting against Se if Se is used in the formation of absorber 20.

### Photoelectrically Active Layer 120

It is contemplated the photovoltaic article has at least a photoelectrically active layer 120. This layer is generally disposed above the flexible conductive substrate 110 and below the top transparent conducting layer 130. This layer functions to take the input from the incident light 16 and convert it into electricity. It is contemplated that this layer may be a single layer of material or may be a multilayer or of many materials, the composition of which may depend upon the type of photovoltaic article 10 (e.g. copper chalcogenide type cork amorphous silicon, III-V (i.e. GaAs), II-IV (i.e. CdTe), copper zinc tin sulfide, organic photovoltaics, nanoparticle photovoltaics, dye sensitized solar cells, and combinations of the like.

The group IB-IIIB chalcogenide (e.g. copper chalcogenide) cells are preferred. In this case the absorber comprises selenides, sulfides, tellurides, and/or combinations of these that include at least one of copper, indium, aluminum, and/or gallium. More typically at least two or even at least three of Cu, In, Ga, and Al are present. Sulfides and/or selenides are preferred. Some embodiments include sulfides or selenides of copper and indium. Additional embodiments include selenides or sulfides of copper, indium, and gallium. Aluminum may be used as an additional or alternative metal, typically replacing some or all of the gallium. Specific examples include: but are not limited to copper indium selenides copper indium gallium selenides, copper gallium selenides, copper indium sulfides, copper indium gallium sulfides, copper gallium sulfides, copper indium sulfide selenides, copper gallium sulfide selenides, copper indium aluminum sulfides, copper indium aluminum selenides, copper indium aluminum sulfide selenide, copper indium aluminum gallium sulfides, copper indium aluminum selenides, copper indium aluminum gallium sulfide selenide, and copper indium gallium sulfide selenides. The absorber materials also may be doped with other materials, such as Na, Li, or the like, to enhance performance. In addition, many chalcogenide materials could incorporate at least some oxygen as an impurity in small amounts without significant deleterious effects upon electronic properties. This layer may be termed by sputtering, evaporation or any other known method. The thickness of this layer is preferably 0.5 to 3 microns.

In the copper chalcogenide cell the optional buffer and window layers may be considered part of either the active layer 120 or the transparent conducting layer 130 for purposes of understanding in what layers the channels are formed. However, preferably the buffer layer is considered part of the active layer 120 and the window layer is considered part of the transparent conducting layer 130.

### Top Transparent Conducting Layer 130

It is contemplated the photovoltaic article 10 has at least a top transparent conducting layer 130. This layer is generally disposed above the photoelectrically active layer 120 and may represent the outer most surface of the article (generally the surface that first receives the incident light 16). This layer is preferably transparent, or at least translucent, and allows the desired wavelengths of light to reach the photoelectrically active layer 120. It is contemplated that this layer may be a single layer of material or may be a multilayer composite of many materials, the composition of which may depend upon the type of photovoltaic article 10 (e.g. copper chalcogenide type cells (e.g. copper indium gallium selenides, copper indium selenides, copper indium gallium sulfides, copper indium sulfides, copper indium gallium selenides sulfides, etc.), amorphous silicon, III-V (i.e., GaAs), II-IV (i.e. CdTe), copper zinc tin sulfide, organic photovoltaics, nanoparticle photovoltaics, dye sensitized solar cells, and combinations of the like. However, preferably the transparent conducting layer 130 is a very thin metal film (such that it is at least somewhat transparent to light) or a transparent conductive oxide A wide variety of transparent conducting oxides; very thin conductive, transparent metal films; or combinations of these may be used, but transparent conductive oxides are preferred. Examples of such TCOs include fluorine-doped tin oxide, tin oxide, indium oxide, indium tin oxide (ITO), aluminum doped zinc oxide (AZO), zinc oxide, combinations of these, and the like. TCO layers are conveniently formed via sputtering or other suitable deposition technique. The transparent conducting layer preferably has a thickness of from 10 to 1500 nm, more preferably 100 to 300 nm.

### Channels

It is contemplated that a number of channels will be “formed” into the article 10 in the process to produce the two or more thin-film-based interconnected photovoltaic cells. These channels function to separate the article into individual cells and can be any number of shapes and sizes. It is contemplated that the channels may be formed vie any number of processes, for example via mechanical scribe, laser ablation, etching (wet or dry), photolithography, or other methods common to the industry for selectively moving material from a substrate. The channels may be of venous widths, depths, and profiles, depending on what may be desired and which channel is being formed (e.g. first, second, or third channels). It is contemplated that the channels may be introduced to the article in the order stated below (e.g. preferably the first channel first, second channel second, third channel third) or in at any other order if so desired.

### First Channel 140

It is contemplated that the first channel 140 be formed through the flexible conductive substrate 110 (and any additional layers that may exist on below or above the substrate) and to such a depth that at least a portion of the photoelectrically active layer is exposed. The first channel functions to both physically and electrically isolate two portions of the article (back side) from each other. In a preferred embodiment, the first channel has a depth that at least exposes a portion of the photoelectrically active layer and can go into the photoelectrically active layer, but not completely through it. It is also preferred that the first channel have a width that allows for the finished cells to flex without the channel closing up. In one preferred embodiment, the first channel has a width FC_{W} that can be about 1 μm to 500 μm. It is preferred that the width is greater than about 10 μm, more preferably greater than about 25 μm, most preferably greater than about 50 μm, and preferably a width less than about 400 μm, and more preferably less than about 300 μm, most preferably less than about 200 μm.

### Second Channel 160

It is contemplated that the second channel 160 be formed through the photoelectrically active layer 120 (and any additional layers that may exist on below or above it) and to such a depth that at least a portion of the flexible conductive substrate is exposed (e.g. at least the electrically conductive portion of it). The second channel functions as a physical path that allows the at least two thin-film-based interconnected photovoltaic cells to be electrically interconnected (e.g. see the applying an electrically conductive material step). It is contemplated that geometrically, the first land second channels be offset from one another, thus minimizing the chance that the first and second channels combine to become a through-hole. In a preferred embodiment, the offset FS_{O} can be about 1 μm to 500 μm. It is preferred that the offset is greater than about 10 μm, more preferably greater than about 25 μm, most preferably greater than about 50 μm, and preferably an offset less than about 400 μm, and more preferably less than about 300 μm, most preferably less than about 200 μm. In a preferred embodiment, the second channel has a depth that at least exposes a portion of the flexible conductive substrate and can go into the flexible conductive substrate, but not completely through it, and most importantly exposes the conductive material (see the applying an electrically conductive material step). It is also preferred that the second channel have a width that allows for the finished cells to flex without the channel closing up. In one preferred embodiment, the second channel has a width SC_{W} that can be about 1 μm to 500 μm. It is preferred that the width is greater thin about 10 μm, more preferably greater than about 25 μm, most preferably greater than about 50 μm, and preferably a width less than about 400 μm, more preferably less than about 300 μm and most preferably less than about 200 μm.

### Third Channel 170

It is contemplated that the third channel 170 be formed through the top transparent conducting layer 130 (and any additional layers that nay exist on below or above the layers) and to the photoelectrically active layer to such a depth that at least a portion of the photoelectrically active layer is exposed. The third channel functions to both physically and electrically isolate two portions of the article (front side) from each other. It is contemplated that geometrically, the third channel is off-set from the first and second channels. In a preferred embodiment, the offset TFS_{O} can be about 1 μm to 500 μm. It is preferred that the width is greater than about 10 μm, more preferably greater than about 25 μm and most preferably greater than about 50 μm, and preferably a width less than about 400 μm, more preferably less than about 300 μm and most preferably less than about 200 μm. In a preferred embodiment, the third channel has a depth that at least exposes a portion of the photoelectrically active layer and can go into the photoelectrically active layer, but not completely through it. It is also preferred that the third channel have a with that allows for the finished cells to flex without the channel closing up. In one preferred embodiment, the third channel has a width TC_{W} that can be about 1 μm to 500 μm. It is preferred that the width is greater than about 10 μm, more preferably greater than about 25 μm, and most preferably greater than about 50 μm and preferably a width less than about 400 μm, and more preferably less than about 300 μm, most preferably less than about 200 μm.

### Forming Channels

It is contemplated that “forming” of the various layers of the article 10 may be achieved via numerous methods, for example as discussed above in the “channels” paragraphs. In one preferred embodiment, a mechanical scribe is utilized to make a “cut”. For example, with mechanical scribing, a diamond-tipped stylus or blade may be placed in contact with the device and dragged across the surface of the device, physically tearing the underlying material in the path of the stylus.

It is contemplated that mechanical scribing, with the use of a diamond-tipped stylus or appropriate blade, may work for the softer semiconductor materials such as CdTe, copper indium gallium diselenide (CIGS), and a-Si:H. It is believed that tearing of the film is a particular problem for films such as zinc oxide (ZnO) that have low adhesion. Mechanical scribing of harder films such as molybdenum on glass invariably leads to scoring of the glass, which then contributes to increased risk of breakage in subsequent processing.

It is also believed that most of the problems encountered with mechanical scribing do not occur with laser scribing. In a recently completed a survey of laser systems, as applied to the thin-film materials used in the CdTe-based and CIS-based PV modules (See:http://www.laserfocusworld.com/articles/print/volume-36/issue-1/features/photovoltaics-laser-scribing-creates-monolithic-thin-film-arrays.html, which is incorporated by reference) has found that good scribes can be obtained with a wide variety of pulsed lasers, such as Nd:YAG (lamp-pumped, diode-pumped, Q-switched, and modelocked), copper-vapor, and xenon chloride and krypton fluoride excimer lasers. It is believed that it may be important when choosing a laser, to pay attention to the specific material properties (absorption coefficient, melting temperature, thermal diffusivity, and so on) of the films used in the solar cells.

### Insulation Segment/Layer 150

It is contemplated that an insulation layer 150 may be disposed at or near the bottom of the finished cells 100. One function of this layer may be to provide a protective barrier (e.g. environmentally and/or electrically) for the portions covered by this layer, keeping out dirt, moisture, and the like. It also can function to hold the cells 100 together, akin to “taping” two adjoining cells together. It is contemplated that layer 150 can span across substantially the entire bottom of the cell 100 or just locally about the area of the channel 140. In a preferred embodiment, the insulation layer 150 can have a thickness IL_{T} of about 100 nm to 1000 μm. It is preferred that the thickness is greater than about 1 μm, more preferably greater than about 25 μm, most preferably greater than about 75 μm, and preferably a thickness less than about 500 μm, more preferably less than about 200 μm and most preferably less than about 100 μm.

The insulation layer may comprise any number of materials that are suitable or providing protection as described above. Preferred materials include: epoxy, silicone, polyester, polyfluorene, polyolefin, polyimide, polyamide polyethylene, polyethylene terephalate, fluoropolymers, paralyene, urethane, ethylene vinyl acetate, or combinations of the like.

It is also contemplated that a layer similar to the insulation layer (at least possibly a similar material) be provided on the top of the article or the call. This layer may function as a carrier layer that may aid in moving or packaging the article and/or the cell. If a carrier layer is provided, it should be readily removable so that the cuts (e.g. formation of the channels) can be made or the finished cells can be installed in a larger PV device.

The carrier layer may comprise any number of materials that are suitable for providing functionality as described above. Preferred materials include materials listed for the insulation layer.

### Electrically Insulating Material (Top of Cell)

It is contemplated that optionally some electrically insulating material may be disposed within the third channel (not shown). This material may function to provide a protective barrier (e.g. environmentally and/or electrically) for the portions covered by the material, keeping out dirt, moisture, and the like. The electrically insulating material may comprise any number of materials that are suitable for providing protection as described above. Preferred materials include: silicon oxide, silicon nitride, silicon carbide, titanium oxide, aluminum oxide, aluminum nitride, boron oxide, boron nitride, boron carbide, diamond like carbon, epoxy, silicone, polyester, polyfluorene, polyolefin, polyimide, polyamide, polyethylene, polyethylene terephalate, fluoropolymers, paralyene, urethane, ethylene vinyl acetate, or combinations of the like.

### Electrically Conductive Material 180

It is contemplated that an electrically conductive material 180 is used in the process to interconnect the photovoltaic cells 100. In the present invention, the material is used in conjunction with the second channel and should be in contact with en electrically conductive portion of the flexible conductive substrate 110 and the top of the top transparent conducting layer 130. The electrically conductive material may comprise any number of materials that are suitable for providing electrical conductivity, but preferred materials include: The electrically conductive material may desirably at least include a conductive metal such as nickel, copper, silver, aluminum, tin, and the like and/or combinations thereof. In one preferred embodiment, the electrically conductive material comprises silver. It is also contemplated that electrically conductive adhesives (ECA) may be any such as are known in the industry. Such ECA's are frequently compositions comprising a thermosetting polymer matrix with electrically conductive polymers. Such thermosetting polymers include but are not limited to thermoset materials having comprising epoxy, cyanate ester, maleimide, phenolic, anhydride, vinyl, allyl or amino functionalities or combinations thereof. The conductive filler particles may be for example silver, gold, copper, nickel, aluminum, carbon nanotubes, graphite, tin, tin alloys, bismuth or combinations thereof. Epoxy based ECAs with silver particles are preferred. The electrically conductive material region can be formed by one of several known methods including but not limited to screen printing, ink jet printing, gravure printing, electroplating, sputtering, evaporating and the like.

The interconnected cells formed by this method can be encapsulated or packaged within protective materials (encapsulants, adhesives, glass, plastic films or sheets, etc.) and electrically interconnected of made electrically connectable to power converters or other electrical devices to form photovoltaic modules that can be installed in the field or on structures to produce and transmit power.

Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention.

The use of the terms “comprising” or “including” describing combinations of elements, ingredients, components or steps herein also contemplates embodiments that consist essentially of the elements, ingredients, components or steps.

Plural elements, ingredients, components or steps can be provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps. All references herein to elements or metals belonging to a certain Group refer to the Periodic Table of the Elements published and copyrighted by CRC Press, Inc., 1989. Any reference to the Group or Groups shall be to the Group or Groups as reflected in this Periodic Table of the Elements using the IUPAC system for numbering groups.

1. A method of producing two or more thin-film-based interconnected photovoltaic cells comprising the steps of:
a) providing a photovoltaic article comprising: a flexible conductive substrate, at least one photoelectrically active layer, and a top transparent conducting layer;
b) forming one or more first channels through the flexible conductive substrate to expose a portion of the photoelectrically active layer;
c) applying an insulating segment to the conductive substrate and spanning the one or more first channel;
d) forming one or more second channels off set from the one or more first channels through the top transparent conducting layer and the photoelectrically active layer to expose a conductive surface of the flexible conductive substrate;
f) forming one or more third channels off set from both the first channels and the second channels, through the top transparent conducting layer and to the photoelectrically active layer; and
g) applying an electrically conductive material above the top transparent conducting layer and in the second channels, thus producing two or more interconnected photovoltaic cells;
wherein the one or more first channels are formed first.

2. The method according to claim 1, further comprising the step of at least partially filling the at least one third off-set channels with an electrically insulating material.

3. The method according to claim 2, wherein the electrically insulating material comprises silicon oxide, silicon nitride, titanium oxide, aluminum oxide, non-conductive epoxy, silicone, polyester, polyfluorene, polyolefin, polyimide, polyamide, polyethylene or combinations thereof.

4. The method according to claim 2, wherein the insulating layer comprises polyester, polyolefin, polyimide, polyamide, polyethylene.

5. The method according to claim 1, wherein the forming step is carried out by scribing, cutting, ablating, or a combination thereof.

6. The method according to claim 1, wherein the photovoltaic article cell is in roll form.

7. (canceled)

8. The method according to claim 1, wherein the third off-set channels of the forming step (f) extend at least partially through the photoelectrically active layer.

9. The method according to claim 1, wherein the width of the channels of the forming step are from 10 to 500 microns.

10. A photovoltaic article formed by the method of any one of claim 10.

11. The method according to claim 1 wherein the one or more first channels, the one or more second channels and the one or more third channels are formed by a scribing process.

12. The method according to claim 1 wherein the one or more first channels, the one or more second channels and the one or more third channels are formed by a mechanical or laser scribing process.
